(19) United States
(12) Patent Application Publication
(10) Pub. No.: US 2023/0403853 A1
(43) Pub. Date: Dec. 14, 2023

(54) NOR-TYPE MEMORY DEVICE, METHOD OF MANUFACTURING NOR-TYPE MEMORY DEVICE, AND ELECTRONIC APPARATUS INCLUDING MEMORY DEVICE

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 18/043,080

(22) PCT Filed: Feb. 22, 2022
(86) PCT No.: PCT/CN2022/077238

§ 371 Date: Feb. 27, 2023

(30) Foreign Application Priority Data
Mar. 8, 2021 (CN) 202110252871.2

(51) Int. Cl. H10B 43/27; H10B 43/10; H10B 41/10; H10B 41/27; H01L 29/786; H01L 29/06; H01L 29/775; H01L 29/423; H01L 29/08

(52) U.S. Cl. CPC H10B 43/27; H10B 43/10; H10B 41/10; H10B 41/27; H01L 29/0847; H01L 29/0673; H01L 29/775; H01L 29/42392; H01L 29/78696

(57) ABSTRACT

An NOR-type memory device, a method of manufacturing the NOR-type memory device, and an electronic apparatus including the NOR-type memory device. The NOR-type memory device includes: a gate stack including a gate conductor layer and a memory functional layer; and a first semiconductor layer and a second semiconductor layer that surround a periphery of the gate stack. The first and second semiconductor layers are respectively located at different heights with respect to the substrate. The memory functional layer is located between the gate conductor layer and each of the first and second semiconductor layers. Each of the first and second semiconductor layers includes a first source/drain region, a channel region, and a second source/drain region that are disposed in sequence in a vertical direction. A memory cell is defined at an intersection of the gate stack and each of the first and second semiconductor layers.

### CROSS REFERENCE TO RELATED APPLICATION(S)

This application claims priority to Chinese Patent Application No. 202110252871.2, filed on Mar. 8, 2021 and entitled “NOR-TYPE MEMORY DEVICE, METHOD OF MANUFACTURING NOR-TYPE MEMORY DEVICE, AND ELECTRONIC APPARATUS INCLUDING MEMORY DEVICE”, the content of which is incorporated herein in its entirety by reference.

### TECHNICAL FIELD

The present disclosure relates to the field of semiconductors, and more particularly, to a NOR-type memory device, a method of manufacturing the NOR-type memory device, and an electronic apparatus including the memory device.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, the planar device is difficult to be further scaled down. In contrast, in a vertical device, a source, a gate and a drain are arranged in a direction substantially perpendicular to a substrate surface. As a result, the vertical device is easier to be scaled down compared to the planar device.

Vertical devices may be stacked to increase an integration density. However, this may lead to poor performance Because in order to stack a plurality of devices conveniently, polycrystalline silicon is usually used as a channel material, resulting in a greater resistance compared with using monocrystalline silicon as the channel material. In addition, it is also desired to adjust a doping level in a source/drain region and a doping level in a channel independently.

### SUMMARY

In view of the above, the present disclosure aims to provide, among others, a NOR-type memory device with an improved performance, a method of manufacturing the NOR-type memory device, and an electronic apparatus including the memory device.

According to an aspect of the present disclosure, there is provided a vertical memory device, including: a gate stack extending vertically on a substrate, wherein the gate stack includes a gate conductor layer and a memory functional layer; and a first semiconductor layer and a second semiconductor layer that surround a periphery of the gate stack and extend along a sidewall of the gate stack, wherein the first semiconductor layer and the second semiconductor layer are respectively located at different heights with respect to the substrate. The memory functional layer is located between the first semiconductor layer and the gate conductor layer, and between the second semiconductor layer and the gate conductor layer. Each of the first semiconductor layer and the second semiconductor layer includes a first source/drain region, a channel region, and a second source/drain region that are disposed in sequence in a vertical direction. A memory cell is defined at each of an intersection of the gate stack and the first semiconductor layer and an intersection of the gate stack and the second semiconductor layer.

According to another aspect of the present disclosure, there is provided a method of manufacturing a vertical memory device, including: disposing a plurality of device layers on a substrate, wherein each of the plurality of device layers includes a stack of a first source/drain defining layer, a first channel defining layer, and a second source/drain defining layer; forming a processing channel that extends vertically with respect to the substrate to pass through the stack in each device layer; epitaxially growing a semiconductor layer on a sidewall of each device layer exposed in the processing channel through the processing channel; and forming a gate stack in the processing channel, wherein the gate stack includes a gate conductor layer and a memory functional layer disposed between the gate conductor layer and the semiconductor layer, and a memory cell is defined at an intersection of the gate stack and the semiconductor layer.

According to another aspect of the present disclosure, there is provided an electronic apparatus including the NOR-type memory device described above.

According to embodiments of the present disclosure, a stack of single crystal material may be used as a building block to build a three-dimensional (3D) NOR-type memory device. Therefore, when a plurality of memory cells are stacked, an increase of resistance may be suppressed. In addition, the semiconductor layer may be in form of a nanosheet, which is particularly beneficial to controlling a short channel effect of the device, reducing a height of the device, increasing the number of device layers, and improving the integration density.

### BRIEF DESCRIPTION OF THE DRAWINGS

The above and other objects, features, and advantages of the present disclosure will become more apparent from following descriptions on embodiments thereof with reference to attached drawings, in which:

FIGS. 1 to 18(c) are schematic diagrams showing some stages in a process of manufacturing a NOR-type memory device according to an embodiment of the present disclosure;

FIGS. 19(a) and 19(b) are schematic diagrams showing some stages in a process of manufacturing a NOR-type memory device according to another embodiment of the present disclosure;

FIGS. 20(a) and 20(b) are schematic diagrams showing some stages in a process of manufacturing a NOR-type memory device according to another embodiment of the present disclosure;

FIG. 21 schematically shows an equivalent circuit diagram of a NOR-type memory device according to an embodiment of the present disclosure,

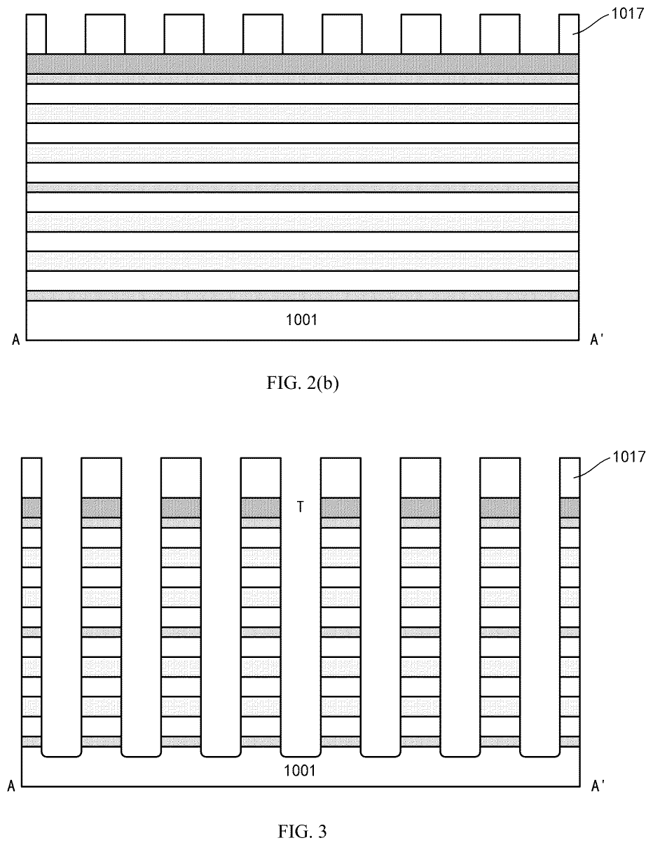

wherein FIGS. 2(a), 12(a), 14(a), 18(a), and 19(a) are top views, and FIG. 2(a) shows positions of line AA′ and line BB′;

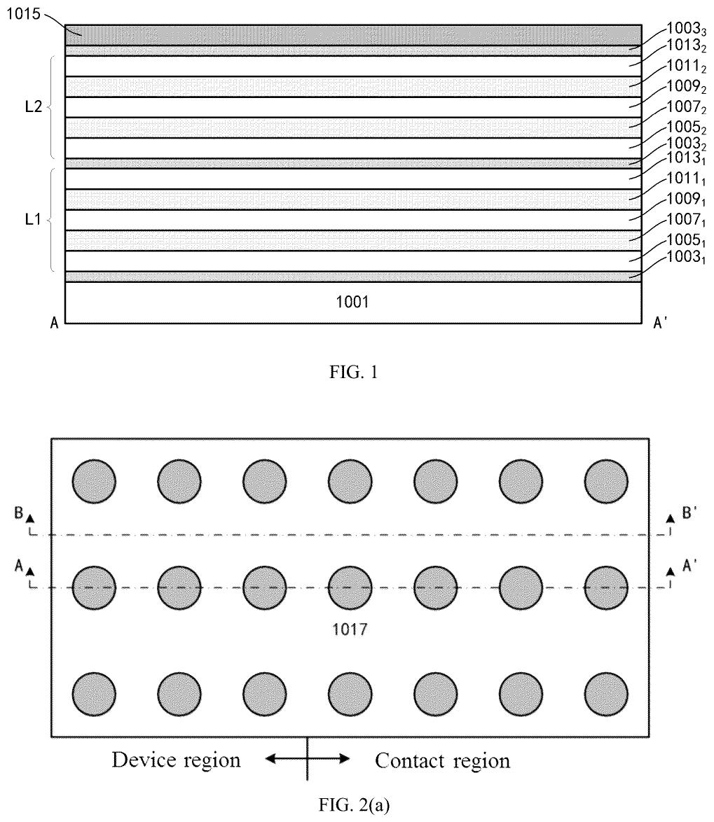

FIGS. 1, 2(b), 3 to 11, 12(b), 13, 14(b), 15(a), 16(a), 17(a), 18(b), 19(b), and 20(a) are cross-sectional views taken along line AA′;

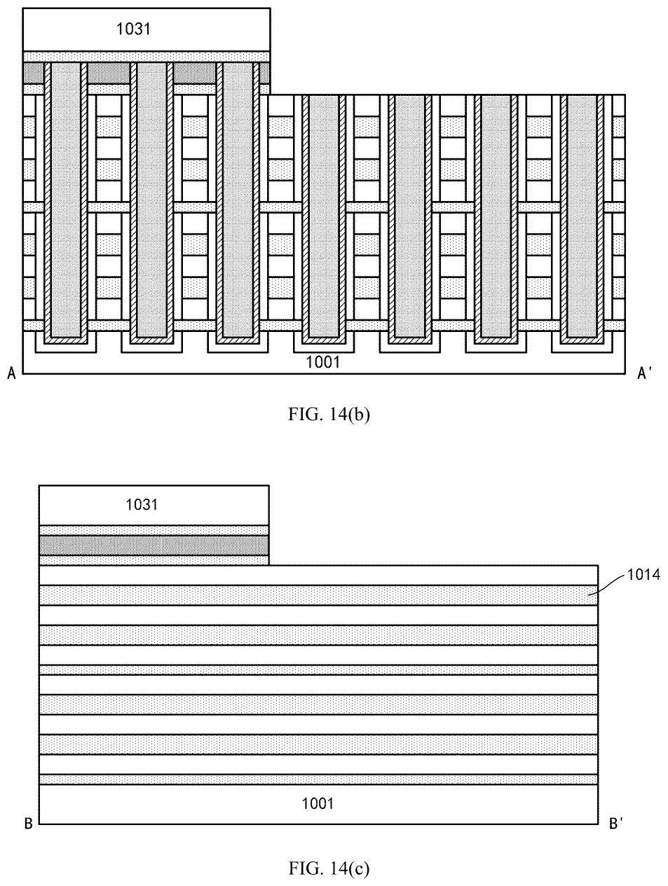

FIGS. 14(c), 15(b), 16(b), 17(b), 18(c), and 20(b) are cross-sectional views taken along line BB′.

Throughout the drawings, the same or similar reference numbers denote the same or similar elements.

### DETAILED DESCRIPTION OF EMBODIMENTS

Hereinafter, descriptions are given with reference to embodiments shown in the attached drawings. However, it is to be understood that these descriptions are illustrative and not intended to limit the present disclosure. Further, in the following, known structures and technologies are not described to avoid obscuring the present disclosure unnecessarily.

In the drawings, various structures according to the embodiments are schematically shown. However, they are not drawn to scale, and some features may be enlarged while some features may be omitted for sake of clarity. Moreover, shapes and relative sizes and positions of regions and layers shown in the drawings are also illustrative, and deviations may occur due to manufacture tolerances and technique limitations in practice. Those skilled in the art may also devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

A memory device according to an embodiment of the present disclosure is based on a vertical device. The vertical device may include an active region arranged on a substrate in a vertical direction (a direction substantially perpendicular to a surface of the substrate). The active region includes source/drain regions at upper and lower ends of the active region and a channel region between the source/drain regions. A conductive channel may be formed between the source/drain regions through the channel region. In the active region, the source/drain regions and the channel region may be defined by, for example, a doping concentration.

According to an embodiment of the present disclosure, the active region may be defined by a semiconductor layer extending vertically. The source/drain regions may be formed at opposite ends of the semiconductor layer respectively, and the channel region may be formed in the middle of the semiconductor layer. A gate stack may extend through the semiconductor layer, so that the active region may surround a periphery of the gate stack. Accordingly, the semiconductor layer may be in form of an annular nanosheet surrounding the gate stack. Here, the gate stack may include a memory functional layer, such as at least one of a charge trapping material or a ferroelectric material, so as to achieve a memory function. In this way, the gate stack is cooperated with an active region opposite to the gate stack, so as to define a memory cell. Here, the memory cell may be a flash memory cell.

Since the vertical device is easy to be stacked, a plurality of such semiconductor layers may be provided in the vertical direction. The gate stack may extend vertically to pass through the plurality of semiconductor layers. The plurality of semiconductor layers may be substantially coplanar in the vertical direction, for example, extending along a sidewall of the gate stack. In this way, for a single gate stack, it intersects the plurality of semiconductor layers stacked in the vertical direction to define a plurality of memory cells stacked in the vertical direction.

A plurality of such gate stacks may be provided, and each gate stack may similarly pass through the plurality of semiconductor layers, thereby defining a plurality of memory cells at intersections of the plurality of gate stacks and the semiconductor layers. Such memory cells may be arranged into a plurality of levels in the vertical direction, and the memory cells in each level are arranged into an array (for example, generally, a two-dimensional array arranged in rows and columns) corresponding to the plurality of gate stacks. Accordingly, a three-dimensional (3D) array of memory cells may be obtained. The memory cells (or semiconductor layers) within each level may be substantially coplanar with each other.

In a NOR (NOT OR)-type memory device, each memory cell may be connected to a common source line. In view of such configuration, every two adjacent memory cells in the vertical direction may share the same source line connection, so as to save wirings. For example, the above-mentioned semiconductor layer may have a configuration of a (first) source/drain region—a (first) channel region—a (second) source/drain region—a (second) channel region—a (third) source/drain region. In this way, the first source/drain region, the first channel region, and the second source/drain region may be cooperated with the gate stack as described above, so as to define a first memory cell. In addition, the second source/drain region, the second channel region, and the third source/drain region may be cooperated with the gate stack likewise, so as to define a second memory cell. The first memory cell and the second memory cell are stacked on each other and share the same second source/drain region. The second source/drain region may be electrically connected to the source line.

In order to achieve an electrical connection to the source/drain region, an interconnection layer contacting the source/drain region may be provided. According to an embodiment of the present disclosure, source/drain regions corresponding to the memory cells in each level may be electrically connected to the bit line(s) or source line(s) through the same interconnection layer. Accordingly, the interconnection layer may be formed to surround each source/drain region in the corresponding level, so that the interconnection layer may be in a shape of plate as a whole, and each semiconductor layer passes through the plate-like interconnection layer. The interconnection layer may extend from the device region where the memory cell is located to a contact region to be formed, so as to fabricate a contact portion to the interconnection layer subsequently.

The source/drain region may be defined by the corresponding interconnection layer. For example, the source/drain region may be formed by driving a dopant in the interconnection layer in the transverse direction into the semiconductor layer. Therefore, the interconnection layer and the corresponding source/drain region may be substantially coplanar in the transverse direction.

Such vertical memory device may be manufactured as follows. Specifically, a plurality of device layers may be disposed on the substrate. Each of the plurality of device layers includes a stack of a first source/drain defining layer, a first channel defining layer, and a second source/drain defining layer (and optionally, a second channel defining layer and a third source/drain defining layer as described above). For example, these layers may be provided by epitaxial growth and may be made of single crystal semiconductor material(s). A thickness of each layer, especially a thickness of the channel defining layer, may be controlled during epitaxial growth. In addition, in situ doping may be performed on each layer, especially the source/drain defining layer, in the stack during epitaxial growth, so as to achieve a desired doping polarity and doping concentration. Here, the channel layer may have etching selectivity with respect to the source/drain defining layer.

A sacrificial layer may be formed between at least one pair of adjacent device layers or even each pair of adjacent device layers. Such sacrificial layer may then be replaced by an isolation layer, so as to electrically isolate an adjacent bit line. The sacrificial layer may have etching selectivity with respect to the device layer.

A processing channel, which extends vertically with respect to the substrate to pass through the stack in the each of the plurality of device layers, may be formed. In the processing channel, a sidewall of the sacrificial layer may be exposed, so that the sacrificial layer may be replaced by the isolation layer. The semiconductor layer may be epitaxially grown on a sidewall of each device layer exposed in the processing channel through the processing channel. Subsequently, the active region, especially the channel region, of the memory cell may be defined by the semiconductor layer. Therefore, the memory cell may be a nanosheet device, which helps to control the short channel effect. The above-mentioned semiconductor layer may be formed by epitaxial growth and may be made of a single crystal semiconductor material. Compared with a conventional process of forming a plurality of gate stacks stacked on each other and then forming a vertical active region which passes through these gate stacks, an active region of single crystal is easier to be formed in the present disclosure.

A dopant in the source/drain defining layer may be diffused in the transverse direction into the semiconductor layer by an annealing treatment, so as to form the source/drain region in the semiconductor layer. A position of the source/drain region relative to the substrate may correspond to a position of the corresponding source/drain defining layer relative to the substrate. When the channel defining layer also contains a dopant, the channel region in the semiconductor layer may also be doped, so as to improve device performance such as improving the short channel effect and adjusting the threshold voltage. It is relatively easy to adjust doping characteristics of the source/drain region and the channel region respectively by doping characteristics of the source/drain defining layer and the channel defining layer.

Before the semiconductor layer is grown, the sidewall of the device layer exposed in the processing channel may be recessed to a certain depth in the transverse direction via the processing channel. The grown semiconductor layer may be located in such recess and may be substantially coplanar in the vertical direction, so that the gate stack subsequently formed in the processing channel may have a relatively planar surface.

A gate stack may be formed in the processing channel.

The present disclosure may be presented in various forms, and some examples of which will be described below. In the following description, the selection of various materials is involved. In selecting the materials, etching selectivity is considered in addition to the function of the materials (for example, a semiconductor material is used to form the active region, a dielectric material is used to form an electrical isolation, and a conductive material is used to form an electrode, an interconnection structure, etc.). In the following description, the required etching selectivity may or may not be indicated. It should be clear to those skilled in the art that when etching a certain material layer is mentioned below, if it is not mentioned that other layers are also etched or the drawing does not show that other layers are also etched, then this etching may be selective, and the material layer may have etching selectivity with respect to other layers exposed to the same etching recipe.

FIGS. 1 to 18(c) are schematic diagrams showing some stages in a process of manufacturing a NOR-type memory device according to an embodiment of the present disclosure.

As shown in FIG. 1, a substrate 1001 is provided. The substrate 1001 may be a substrate in any form, for example, but not limited to, a bulk semiconductor material substrate such as a bulk silicon (Si) substrate, a Semiconductor On Insulator (SOI) substrate, a compound semiconductor substrate such as an SiGe substrate, or the like. Hereinafter, the bulk Si substrate, such as a Si wafer, will be described by way of example for the convenience of description.

On the substrate 1001, a memory device, such as a NOR-type flash memory, may be formed as described below. A memory cell in the memory device may be an n-type device or a p-type device. Here, an n-type memory cell is described as an example. For this purpose, a p-type well may be formed in the substrate 1001. Therefore, the following description, in particular the description of a doping type, is for forming the n-type device. However, the present disclosure is not limited thereto.

On the substrate 1001, a sacrificial layer 1003₁ used to define the isolation layer, a first source/drain defining layer 1005₁ used to define the source/drain region, a first channel defining layer 1007₁ used to define the channel region, a second source/drain defining layer 1009₁ used to define the source/drain region, a second channel defining layer 1011₁ used to define the channel region, and a third source/drain defining layer 1013₁ used to define the source/drain region may be formed by, for example, epitaxial growth. The first source/drain defining layer 1005₁, the first channel defining layer 1007₁, the second source/drain defining layer 1009₁, the second channel defining layer 1011₁, and the third source/drain defining layer 1013₁ will then define a position of an active region of the device, and may be referred to as “device layer” which is denoted as L1 in FIG. 1.

Each layer grown on the substrate 1001 may be a single crystal semiconductor layer. These layers may have a crystal interface or a doping concentration interface between each other because they are grown or doped separately.

The sacrificial layer 1003₁ may then be replaced by an isolation layer used to isolate the device from the substrate. A thickness of the sacrificial layer 1003₁ may correspond to a thickness of the isolation layer that is desired to be formed, for example, about 10 nm to 50 nm. According to a circuit design, the sacrificial layer 1003₁ may be omitted. Each of the first source/drain defining layer 1005₁, the second source/drain defining layer 1009₁, and the third source/drain defining layer 1013₁ may define a source/drain region by doping (for example, in situ doping during growth), and may have a thickness of about 20 nm to 50 nm, for example. Each of the first channel defining layer 1007₁ and the second channel defining layer 1011₁ may define a gate length, and may have a thickness corresponding to a gate length that is desired to be formed, for example, about 15 nm to 100 nm.

These semiconductor layers may include various suitable semiconductor materials, for example, an element semiconductor material such as Si or Ge, a compound semiconductor material such as SiGe, etc. Considering the following process, adjacent ones of these semiconductor layers may have etching selectivity with respect to each other. For example, the sacrificial layer 1003₁, the first channel defining layer 1007₁, and the second channel defining layer 1011₁ may include SiGe (an atomic percentage of Ge, for example, is about 15% to 30%), and the first source/drain defining layer 1005₁, the second source/drain defining layer 1009₁, and the third source/drain defining layer 1013₁ may include Si.

The first source/drain defining layer 1005₁, the second source/drain defining layer 1009₁, and the third source/drain defining layer 1013₁ may be doped in situ when growing, so as to be used to form the source/drain regions subsequently. For example, for the n-type device, an n-type doping may be performed, and a doping concentration may be, for example, about 1E19 cm⁻³ to 1E21 cm⁻³.

In order to increase an integration density, a plurality of device layers may be provided. For example, a device layer L2 may be provided on the device layer L1 by epitaxial growth. The device layer L1 is separated from the device layer L2 by a sacrificial layer 1003₂ used to define the isolation layer. Although only two device layers are shown in FIG. 1, the present disclosure is not limited thereto. According to the circuit design, it is possible to omit the isolation layer between certain device layers. Similarly, the device layer L2 may have a first source/drain defining layer 1005₂, a first channel defining layer 1007₂, a second source/drain defining layer 1009₂, a second channel defining layer 1011₂, and a third source/drain defining layer 1013₂. Respective layers in each device layer L1 and L2 may have the same or similar thickness and/or material, or may have different thicknesses and/or materials. Here, for convenience of description only, it is assumed that each device layer L1 and L2 has the same configuration.

On such layers formed on the substrate 1001, a hard mask layer 1015 may be provided to facilitate patterning. For example, the hard mask layer 1015 may include nitride (for example, silicon nitride). A thickness of the hard mask layer 1015 is about 50 nm to 200 nm.

It is also possible to provide a sacrificial layer 1003₃, which is used to define the isolation layer, between the hard mask layer 1015 and the device layer L2. For sacrificial layers 1003₂ and 1003₃, reference may be made to the above description of sacrificial layer 1003₁. Considering the following process, a thickness of each of the sacrificial layers 1003₁, 1003₂, and 1003₃ may be different from, e.g. less than, a thickness of each of the channel defining layers 1007₁, 1011₁, 1007₂, and 1011₂.

In the following, on the one hand, a processing channel which may reach the sacrificial layer is desired, so as to replace the sacrificial layer by the isolation layer. On the other hand, it is desired to define a region used to form a gate. According to an embodiment of the present disclosure, the two aspects may be implemented in combination. Specifically, a gate region may be defined by the processing channel.

For example, as shown in FIGS. 2(a) and 2(b), a photoresist 1017 may be formed on the hard mask layer 1015. The photoresist 1017 may be patterned to have a plurality of openings by photolithography, and these openings may define positions of the processing channels. The opening may have various suitable shapes, such as round, rectangular, square, polygon, etc. and has a suitable size, such as a diameter or side length of about 20 nm to 500 nm. Considering the following process, the size of the opening may be greater than the thickness of each of the sacrificial layers 1003₁, 1003₂, and 1003₃ as well as the thickness of each of the channel defining layers 1007₁, 1011₁, 1007₂, and 1011₂. Here, these openings (especially in the device region) may be arranged in form of an array, such as a two-dimensional array along horizontal and vertical directions in paper in FIG. 2(a). The array may then define an array of memory cells. Although the openings are shown to be formed on the substrate (including the device region where the memory cell will be fabricated subsequently and the contact region where a contact portion will be fabricated subsequently) with a basically consistent size and a substantially uniform density in FIG. 2(a), the present disclosure is not limited thereto. The size and/or density of the openings may be changed. For example, a density of the openings in the contact region may be less than a density of the openings in the device region, so as to reduce the resistance in the contact region.

As shown in FIG. 3, the patterned photoresist 1017 may be used as an etching mask to etch each layer on the substrate 1001 by anisotropic etching, such as reactive ion etching (RIE), so as to form a processing channel T. RIE may be performed in a substantially vertical direction (for example, a direction perpendicular to the substrate surface) and may be performed into the substrate 1001. Accordingly, a plurality of vertical processing channels T are left on the substrate 1001. A processing channel T in the device region also defines the gate region. Then, the photoresist 1017 may be removed.

Currently, the sidewall of the sacrificial layer is exposed in the processing channel T. Accordingly, the sacrificial layer may be replaced by the isolation layer via the exposed sidewall. Considering a function of supporting the device layers L1 and L2 during replacement, a support layer may be formed.

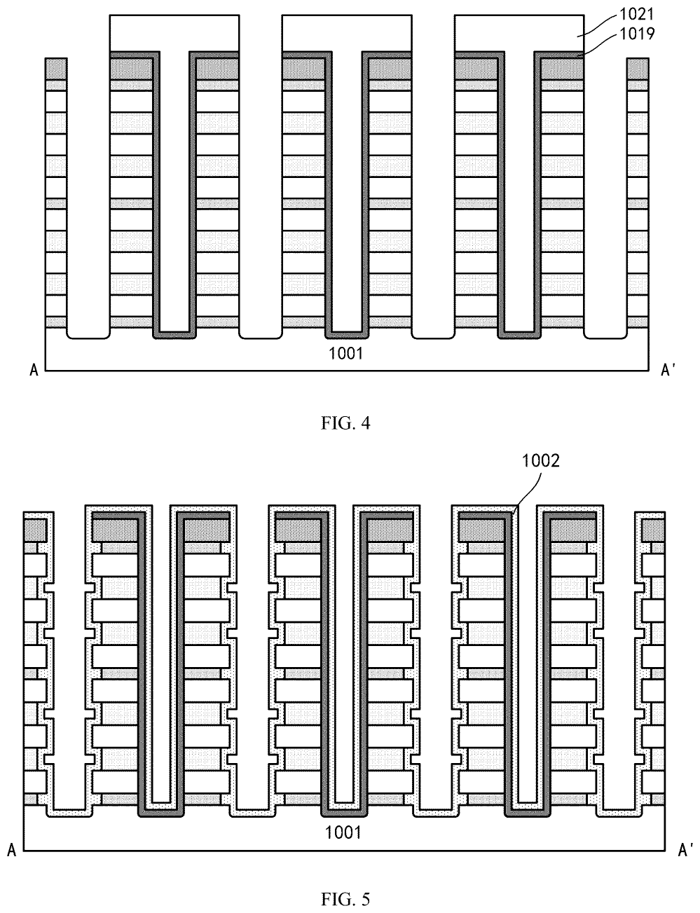

For example, as shown in FIG. 4, a support material layer may be formed on the substrate 1001 by, for example, deposition, such as chemical vapor deposition (CVD). The support material layer may be formed in a substantially conformal manner. Considering the etching selectivity, especially the etching selectivity with respect to the hard mask layer 1015 (nitride in this example) and the subsequently formed isolation layer (oxide in this example), the support material layer may include, for example, SiC. By forming a photoresist 1021 and performing selective etching such as RIE with the photoresist 1021 for example, a part of the support material layer in one or more of processing channels T may be removed while a part of the support material layer in the rest of processing channels T may be retained. The remaining part of the support material layer forms a support layer 1019. In this way, on the one hand, the sacrificial layer may be replaced via a processing channel in which the support layer 1019 is not formed, and on the other hand, the device layers L1 and L2 may be supported by the support layer 1019 in the rest of processing channels. After that, the photoresist 1021 may be removed.

An arrangement of the processing channel in which the support layer 1019 is formed and the processing channel in which the support layer 1019 is not formed may be achieved by a pattern of the photoresist 1021. In addition, the processing channel in which the support layer 1019 is formed and the processing channel in which the support layer 1019 is not formed may be substantially evenly distributed for process consistency and uniformity. As shown in FIG. 4, the processing channel in which the support layer 1019 is formed and the processing channel in which the support layer 1019 is not formed may be arranged alternately.

Accordingly, the sacrificial layer may be replaced via the processing channel while the device layer is supported by the support layer 1019. However, in this example, both the sacrificial layer and the channel defining layer include SiGe. In this case, the operation of replacing the isolation layer may affect the channel defining layer. A protective plug self-aligned with the channel defining layer may be formed to prevent the channel defining layer from being affected by the operation of replacing the isolation layer. It should be pointed out that when the sacrificial layer and the channel defining layer have etching selectivity with respect to each other, the operation of forming the protective plug may be omitted.

For example, as shown in FIG. 5, the channel defining layers 1007₁, 1011₁, 1007₂, and 1011₂ may be relatively recessed (with respect to upper and lower source/drain defining layers) in the transverse direction by selective etching. Atomic layer etching (ALE) may be used to control the etching depth. Accordingly, a protective gap self-aligned with the channel defining layer is formed. The protective plug may then be formed in the protective gap. Here, similarly, the sacrificial layers 1003₁ to 1003₃ will be relatively recessed to form an isolation gap.

In order to avoid further forming the protective plug in the isolation gap to affect the replacement of the sacrificial layer, a position holding plug may be formed in the isolation gap. For example, a position holding material layer 1002 may be formed by deposition. A deposition thickness of the position holding material layer 1002 may be greater than half of a thickness of the isolation gap (i.e., half of the thickness of the sacrificial layer), but less than half of a thickness of the protective gap (i.e., half of the thickness of the channel defining layer). In addition, since the size of the processing channel is relatively large, the processing channel may not be fully filled with the position holding material layer 1002. Atomic layer deposition (ALD) may be used to control the deposition thickness. Considering etching selectivity, the position holding material layer 1002 may include, for example, oxide.

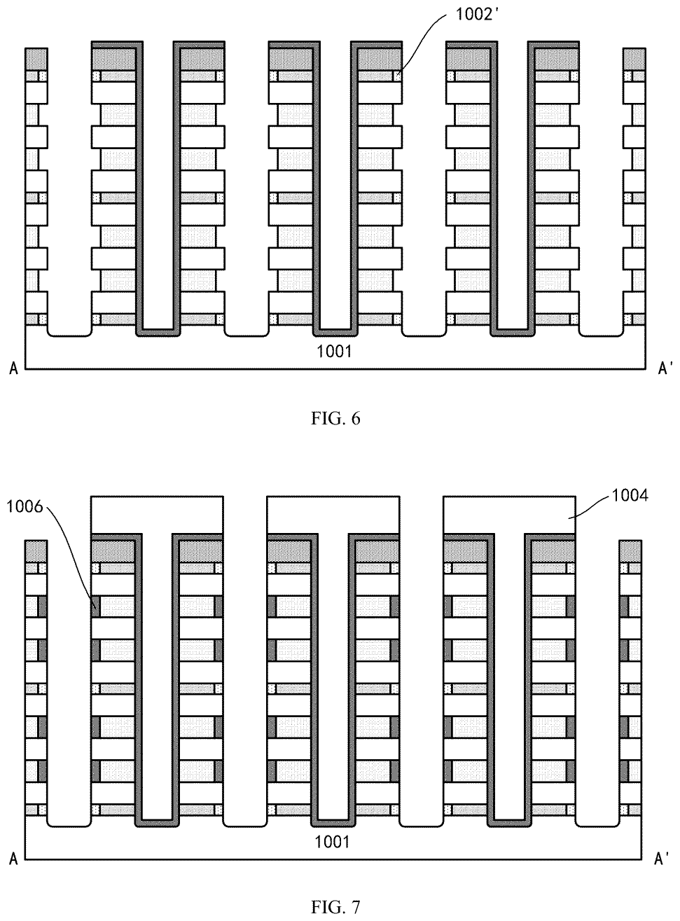

Next, as shown in FIG. 6, the position holding material layer 1002 with a certain thickness may be removed by selectively etching. For example, a removal thickness of the position holding material layer 1002 may be substantially equal to or slightly greater than the deposition thickness of the position holding material layer 1002. Accordingly, the position holding material layer 1002 may be removed from the protective gap and left in the isolation gap, so as to form a position holding plug 1002′. ALE may be used to control the removal thickness.

Next, a protective plug 1006 may be formed in the protective gap, as shown in FIG. 7. For example, the protective plug 1006 may be formed by deposition followed by RIE in the vertical direction. Considering the etching selectivity (with respect to the position holding plug 1002′ and the hard mask layer 1015), the protective plug 1006 may include, for example, SiC (which may be removed along with the support layer 1019, which is also SiC, in the subsequent process. Of course, the protective plug 1006 may also include a material different from the material of the support layer 1019, in which case the protective plug 1006 may be removed by separate etching in the subsequent steps). When etching to form the protective plug 1006, the support layer 1019 may be covered by a photoresist 1004 to avoid the removal of the support layer 1019. Then, the photoresist 1004 may be removed.

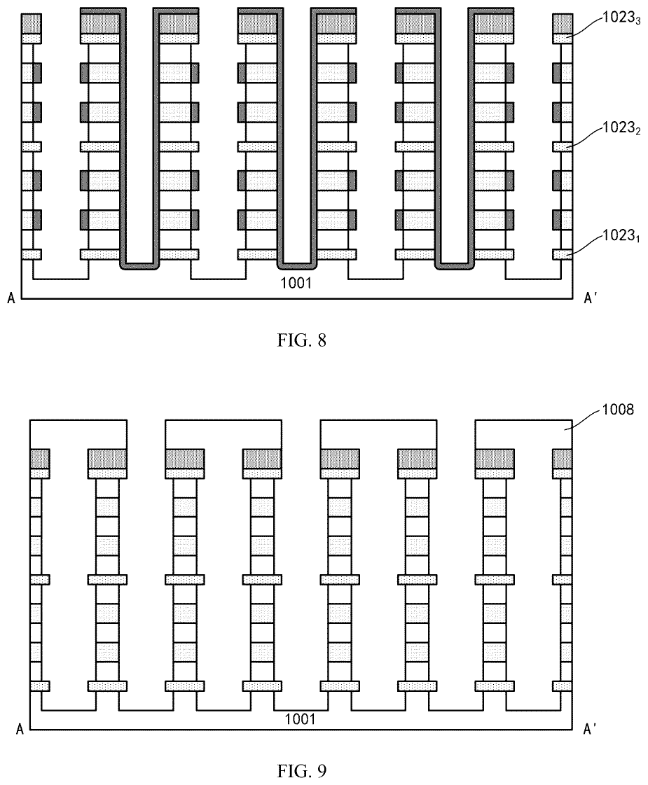

Next, as shown in FIG. 8, the position holding plug 1002′ may be removed by selective etching via the processing channel T to expose the sacrificial layers 1003₁, 1003₂, and 1003₃, and the exposed sacrificial layers 1003₁, 1003₂, and 1003₃ may be removed by selective etching via the processing channel T. Due to the existence of the support layer 1019, the device layers L1 and L2 may be kept from collapsing. Gaps obtained by the removal of the sacrificial layers may be filled with a dielectric material to form isolation layers 1023₁, 1023₂, and 1023₃ by a process of e.g. depositing (preferably atomic layer deposition (ALD) to better control a film thickness) and then etching back (for example, RIE in the vertical direction). A suitable dielectric material, such as oxide, nitride, SiC or a combination of oxide, nitride, or SiC, may be selected for various purposes, such as optimizing reliability of isolation, leakage current or capacitance. Here, in consideration of etching selectivity, the isolation layers 1023₁, 1023₂ and 1023₃ may include oxide (for example, silicon oxide).

In the above example, the position holding plug 1002′ is formed in advance in order to form the protective plug 1006. However, the present disclosure is not limited thereto. For example, the thickness of the channel defining layer may be less than that of the sacrificial layer. In this case, the protective plug may be formed in the protective gap self-aligned with the channel defining layer in the same manner as that of forming the position holding plug 1002′, while a space of the isolation gap may be reserved. The sacrificial layer may be exposed through the isolation gap and thus may be replaced.

Since the channel defining layer was recessed relatively to form the self-aligned protective plug 1006, the source/drain defining layer may also be recessed to a certain extent in the transverse direction by selective etching, in consideration of the subsequent semiconductor layer growth process and the isolation between the grown semiconductor layers. The transverse recess extent of the source/drain defining layer may be substantially the same as that of the channel defining layer, so that the source/drain defining layer and the channel defining layer may have substantially coplanar sidewalls. Subsequently, the semiconductor layer may be grown on such substantially planar sidewalls.

Next, the support layer 1019 may be removed by selective etching. The protective plug 1006 may be removed as the support layer 1019 is removed.

In the processing channel where the support layer 1019 has not been formed, the sidewall of the current device layer is recessed to a certain extent in the transverse direction with respect to the sidewall of the opening in the hard mask layer 1015 due to the above processing. In the processing channel where the support layer 1019 has been formed, the sidewall of the current device layer is consistent with the sidewall of the opening in the hard mask layer 1015. Considering the isolation between the subsequently grown semiconductor layers, the sidewall of the device layer in the processing channel where the support layer 1019 has been formed may also be recessed to a certain extent in the transverse direction. The sidewalls of the device layer in respective processing channels may be recessed to substantially the same extent in transverse direction. For example, as shown in FIG. 9, a photoresist 1008 may be formed and patterned to cover the processing channel where the support layer 1019 has not been formed, while the processing channel where the support layer 1019 has been formed is exposed. Through the exposed processing channel, the device layer may be relatively recessed by selective etching. The selective etching of the channel defining layer in the device layer and the selective etching of the source/drain defining layer in the device layer may be performed separately, and their etching depths may be substantially the same. Then, the photoresist 1008 may be removed.

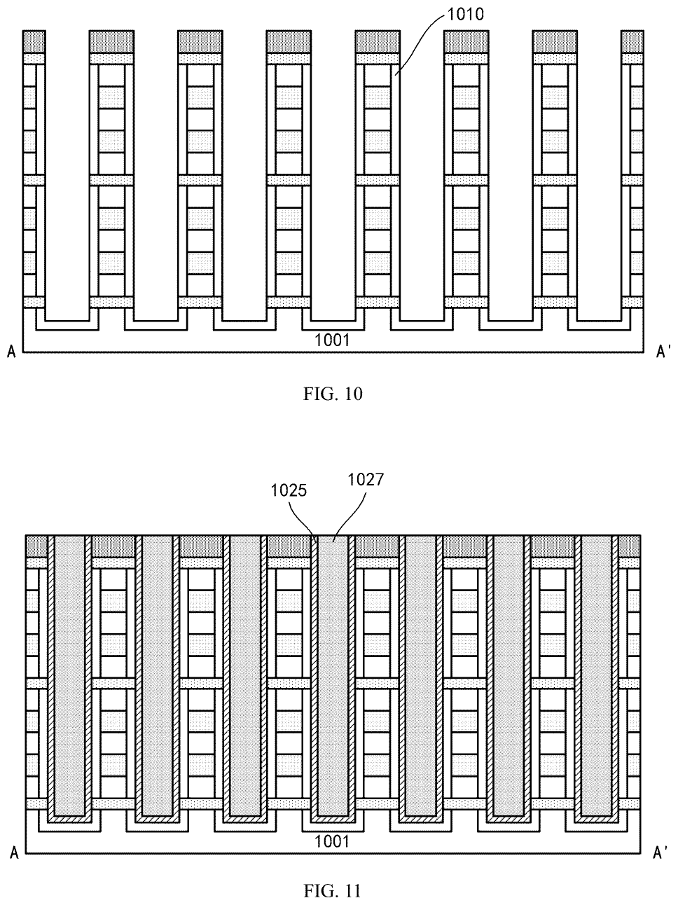

Next, as shown in FIG. 10, a semiconductor layer 1010 may be respectively formed on a sidewall of each device layer L1 and L2, for example, by selective epitaxial growth. The semiconductor layer 1010 may be formed as an annular nanosheet surrounding the processing channel. The semiconductor layer 1010 may include various suitable semiconductor materials such as Si. A material and/or thickness of the semiconductor layer 1010 may be selected to improve the device performance. For example, the semiconductor layer 1010 may include Ge, IV-IV compound semiconductor such as SiGe, III-V compound semiconductor, etc., so as to improve the carrier mobility or reduce the leakage current. Adjacent semiconductor layers 1010 in the vertical direction may be isolated from each other by the isolation layer.

Annealing treatment may be performed to drive the dopant in the source/drain defining layer into the semiconductor layer 1010, so as to form the source/drain region in a portion of the semiconductor layer 1010 which corresponds to the source/drain defining layer in height. Here, since the semiconductor layer 1010 is relatively thin, a process parameter such as an annealing time may be controlled such that a doping distribution in the semiconductor layer 1010 mainly depends on the transverse diffusion from the device layer while the vertical diffusion substantially do not affect or has minor affect on the doping distribution in the semiconductor layer 1010. The channel defining layer may also be doped in situ during growth, so that a certain doping distribution may be formed in a portion of the semiconductor layer 1010 which corresponds to the channel defining layer in height during the annealing treatment, so as to define the doping characteristic of the channel region. Alternatively, the semiconductor layer 1010 may be doped in situ during growth to define the doping characteristic of the channel region. Doping in the channel region may improve the device performance, such as improving the short channel effect and adjusting the threshold voltage (Vt).

The gate stack may be formed in the processing channel, especially in the processing channel of the device region. Here, a memory function may be achieved by the gate stack for forming the memory device. For example, the gate stack may include a memory structure, such as a charge trapping material or a ferroelectric material.

As shown in FIG. 11, a memory functional layer 1025 and a gate conductor layer 1027 may be formed sequentially by, for example, deposition. The memory functional layer 1025 may be formed in a substantially conformal manner. A gap obtained after the memory functional layer 1025 is formed in the processing channel T may be filled with the gate conductor layer 1027. A planarization treatment, such as chemical mechanical polishing (CMP, for example, CMP may stop at the hard mask layer 1015), may be performed on the formed gate conductor layer 1027 and the formed memory function layer 1025, so that the gate conductor layer 1027 and the memory functional layer 1025 may be left in the processing channel T to form the gate stack.

The memory functional layer 1025 may be based on a dielectric charge trapping, a ferroelectric material effect or a bandgap engineering charge memory (SONOS), etc. For example, the memory functional layer 1025 may include a dielectric tunneling layer (such as an oxide with a thickness of about 1 nm to 5 nm, which may be formed by oxidation or ALD), an energy band offset layer (such as a nitride with a thickness of about 2 nm to 10 nm, which may be formed by CVD or ALD), and an isolation layer (such as an oxide with a thickness of about 2 nm to 6 nm, which may be formed by oxidation, CVD or ALD). Such three-layer structure may lead to an energy band structure that traps an electron or a hole. Alternatively, the memory functional layer 1025 may include a ferroelectric material layer, such as HfZrO₂ with a thickness of about 2 nm to 20 nm.

The gate conductor layer 1027 may include, for example, (doped, such as p-doped in the case of the n-type device) polysilicon or a metal gate material.

The channel defining layer may be removed, so that the channel region may be completely formed in the semiconductor layer 1010. Accordingly, a nanosheet device may be obtained.

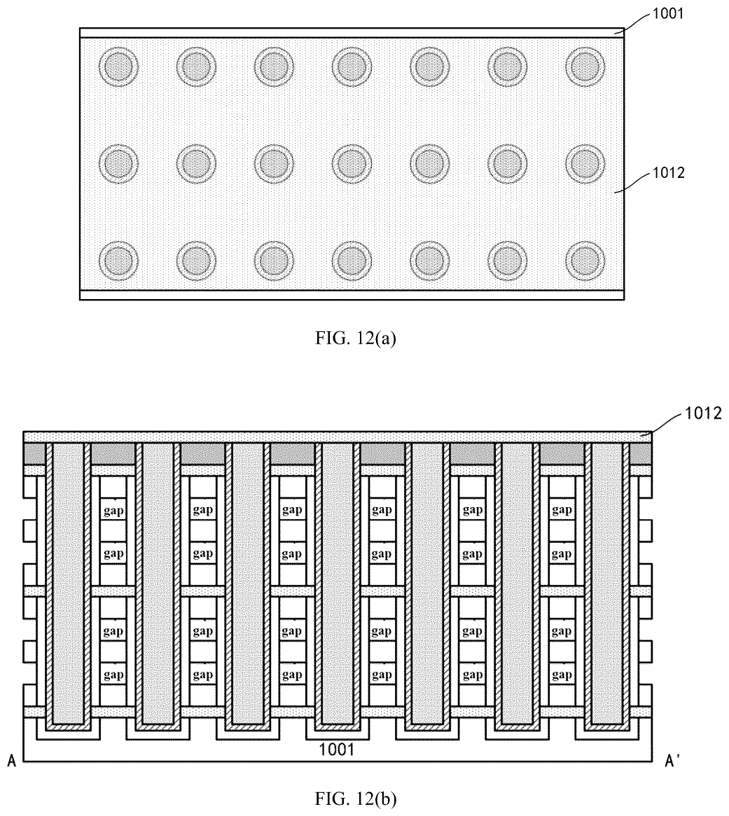

To remove the channel defining layer, it is desired to form a (additional) processing channel to each channel limiting layer (because the previously formed processing channels have been occupied by the gate stack). For example, as shown in FIGS. 12(a) and 12(b), a mask layer 1012, such as oxide, may be formed on the hard mask layer 1015. The mask layer 1012 is patterned to expose a region where the processing channel needs to be formed. The processing channel may be formed where the gate stack is not disposed. In the example of FIGS. 12(a) and 12(b), a processing channel extending along a second direction (a horizontal direction in-paper in FIG. 12(a)) that intersects with (for example, perpendicular to) the first direction (the vertical direction in-paper in FIG. 12(a)) may be disposed every few memory cells (three memory cells in the example of FIG. 12(a)) in the first direction. The photoresist 1012 may be used as an etching mask to etch each layer below the photoresist 1012 by anisotropic etching, such as the RIE in the vertical direction. The etching may be performed into the substrate 1001, so that the processing channel is defined, and each channel defining layer is exposed in the processing channel. Each channel defining layer may be removed by selective etching via the processing channel.

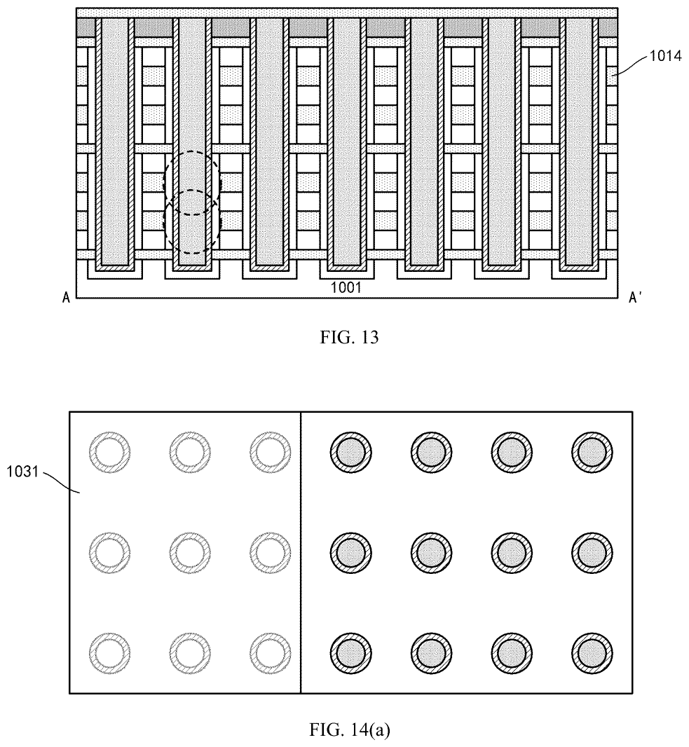

As shown in FIG. 13, a gap (and a processing channel) obtained by the removal of the channel defining layer may be filled with a dielectric 1014 such as oxide by deposition, so as to achieve structural support and electrical isolation. A planarization treatment such as CMP may be performed on the deposited dielectric 1014. Since the mask layer 1012 also includes oxide, the mask layer 1012 is shown integrally with the dielectric 1014.

As shown in FIG. 13, the gate stack (1025/1027) having the memory functional layer is surrounded by the semiconductor layer 1010. The gate stack is cooperated with the semiconductor layer 1010 to define the memory cell, as shown in a dotted circle in FIG. 13. As described above, the source/drain regions are formed in portions corresponding to the source/drain defining layer at the upper and lower ends of the semiconductor layer 1010, and the channel region is formed in a portion corresponding to the channel defining layer in the middle of the semiconductor layer 1010. The channel region may be connected to source/drain regions at opposite ends of the channel region, and the channel region may be controlled by the gate stack.

The gate stack extends in a column shape in the vertical direction and intersects with a plurality of semiconductor layers, so as to define a plurality of memory cells stacked on each other in the vertical direction. Memory cells associated with a single gate stack column may form a memory cell string. Corresponding to an arrangement of the gate stack columns (corresponding to the above arrangement of the processing channels T, such as the two-dimensional array), a plurality of such memory cell strings are arranged on the substrate, so as to form a three-dimensional (3D) array of memory cells.

In this embodiment, the single gate stack column may define two memory cells in a single device layer, as shown by two dotted circles in the device layer L1 in FIG. 13. In the NOR-type memory device, such two memory cells may share the same source/drain region (a portion in the semiconductor layer 1010 which corresponds to the middle second source/drain defining layer 1009₁ or 1009₂ in height), and may be electrically connected to the source line through the second source/drain defining layer 1009₁ or 1009₂. In addition, other source/drain regions (portions in the semiconductor layer 1010 that correspond to the first source/drain defining layer 1005₁ or 1005₂ and the third source/drain defining layer 1013₁ or 1013₂ in height) of the two memory cells may be electrically connected to different bit lines through the corresponding source/drain defining layers. That is, the source/drain defining layer may be used as an interconnection structure to electrically connect the source/drain region of the memory cell to the bit line or source line. The channel region is formed in the semiconductor layer 1010 in the form of circular nanosheet, so the device may be a nanosheet or nanowire device, which may achieve good short channel effect control and power reduction.

In this way, the fabrication of the memory cell (in the device region) is completed. Then, various electrical contact portions may be fabricated (in the contact region) to achieve a desired electrical connection.

In order to achieve an electrical connection to each device layer, a step structure may be formed in the contact region. Such step structure may be formed in various manners in the art. According to an embodiment of the present disclosure, the step structure may be formed as follows, for example.

As shown in FIGS. 14(a), 14(b), and 14(c), a photoresist 1031 may be formed on the dielectric 1014 (including the mask layer 1012). The photoresist 1031 is patterned by photolithography to shield the device region and expose the contact region. Selective etching such as RIE may be performed on the dielectric 1014, the hard mask layer 1015, the isolation layer 1023₃, and the gate stack by using the photoresist 1031 as an etching mask, so as to expose the device layer. A surface exposed by the photoresist 1031 in the contact region after etching may be substantially planar by controlling an etching depth. For example, the dielectric 1014 above the hard mask layer 1015 may be etched, so as to expose the gate stack; and then the gate conductor layer 1027 is etched. The etching of the gate conductor layer 1027 may be stopped near a top surface of the device layer L2. Then the hard mask layer 1015 and the isolation layer 1023₃ may be etched sequentially. After such etching, a top end of the memory functional layer 1025 may protrude above the top surface of the device layer L2 and may be removed by RIE. In this way, a step is formed between the contact region and the device region. Then, the photoresist 1031 may be removed.

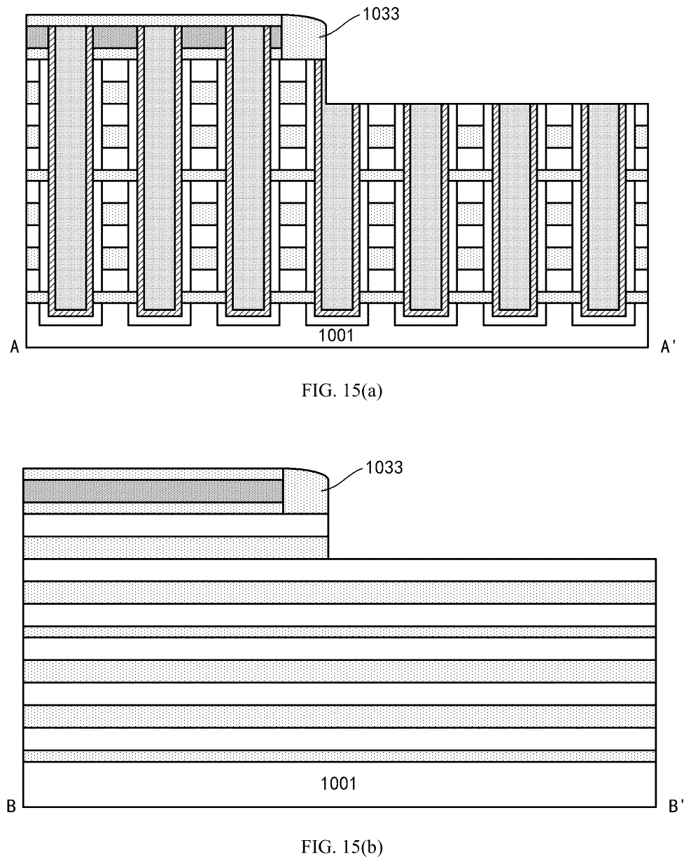

As shown in FIGS. 15(a) and 15(b), a spacer 1033 may be formed at the step between the contact region and the device region through a spacer formation process. For example, a layer of dielectric such as oxide may be deposited in a substantially conformal manner, and then anisotropic etching such as RIE in the vertical direction may be performed on the deposited dielectric, so as to remove a transverse extending portion of the deposited dielectric and retain a vertical extending portion of the deposited dielectric, thereby forming the spacer 1033. Here, considering that the dielectric 1014 also includes oxide, an etching depth of the RIE may be controlled to be substantially equal to or slightly greater than a deposition thickness of the dielectric, so as to avoid completely removing the dielectric 1014 above the hard mask layer 1015. A width of the spacer 1033 (in the horizontal direction in FIGS. 15(a) and 15(b)) may be basically equal to the deposition thickness of the dielectric. The width of the spacer 1033 defines a size of a landing pad of a contact portion to the third source/drain defining layer 1013₂ in the device layer L2.

Selective etching such as RIE may be performed on the exposed third source/drain defining layer 1013₂, the dielectric 1014, and the gate stack by using the formed spacer 1033 as an etching mask, so as to expose the second source/drain defining layer 1009₂ in the device layer L2. A surface exposed by the spacer 1033 in the contact region after etching may be substantially planar by controlling an etching depth. For example, the gate conductor layer 1027 may be etched (when the gate conductor layer 1027 includes polycrystalline Si, at least a part of the third source/drain defining layer 1013₂, which is made of Si herein, may also be etched), and the etching may be stopped near a top surface of the second source/drain defining layer 1009₂. Then the third source/drain defining layer 1013₂ may be etched (for example, the third source/drain defining layer 1013₂ was not completely etched before; or the gate conductor layer 1027 includes a metal gate, and thus an etching recipe with etching selectivity is used), and the etching may be stopped at the dielectric 1014. Then the dielectric 1014 may be etched, and the etching of the dielectric 1014 may be stopped at the second source/drain defining layer 1009₂. After such etching, the top end of the memory functional layer 1025 may protrude above the top surface of the second source/drain defining layer 1009₂ and may be removed by RIE. In this way, another step is formed between the third source/drain defining layer 1013₂ and the surface exposed by the spacer 1033 in the contact region.

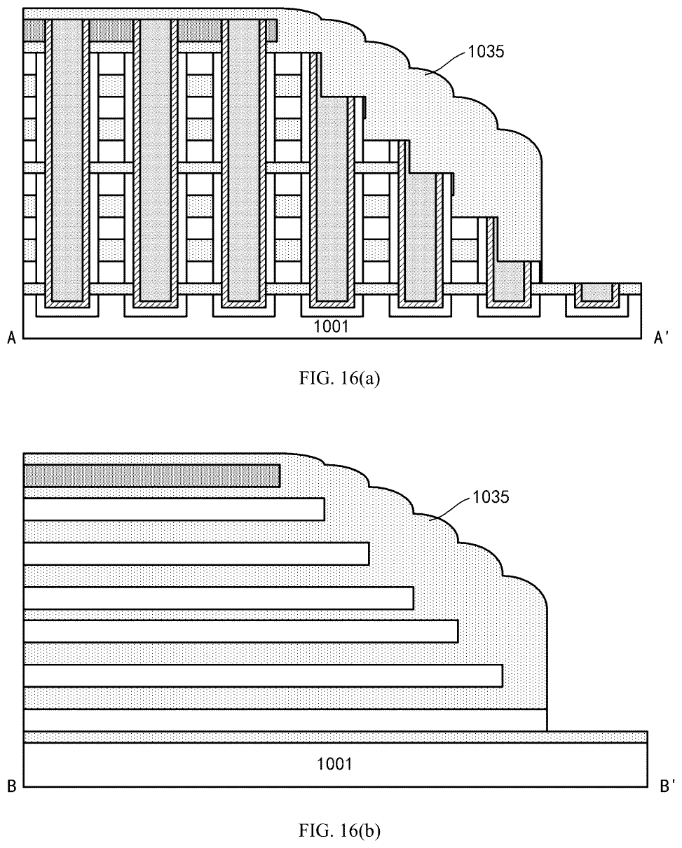

According to the process described above in combination with FIGS. 15(a) and 15(b), the spacer is formed and etching is performed by taking the spacer as the etching mask. Accordingly, a plurality of steps may be formed in the contact region, as shown in FIGS, 16(a) and 16(b). Such steps form such a step structure that in each device layer, each layer to be electrically connected such as the above described source/drain defining layer, has an end portion protruded with respect to the upper layer, so as to define a landing pad of a contact portion to the layer. A portion of each formed spacer being left after processing is denoted by 1035 in FIGS. 16(a) and 16(b).

Next, the contact portion may be fabricated.

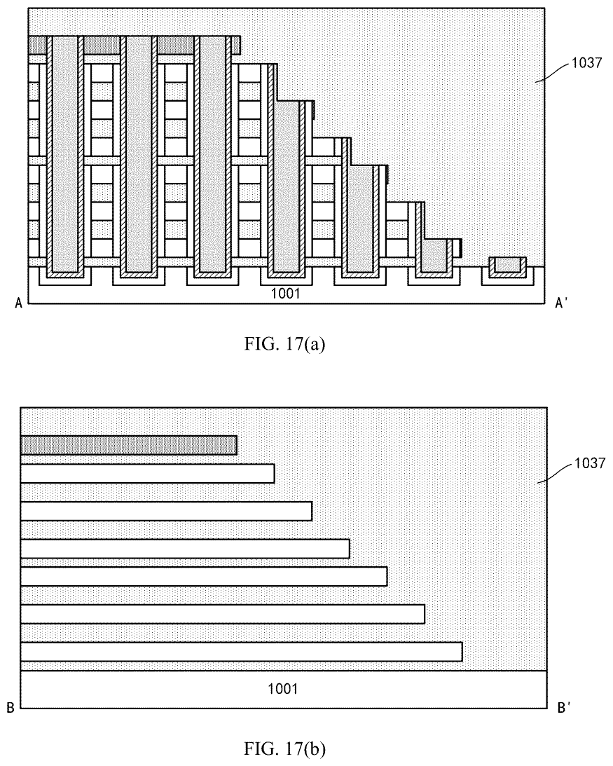

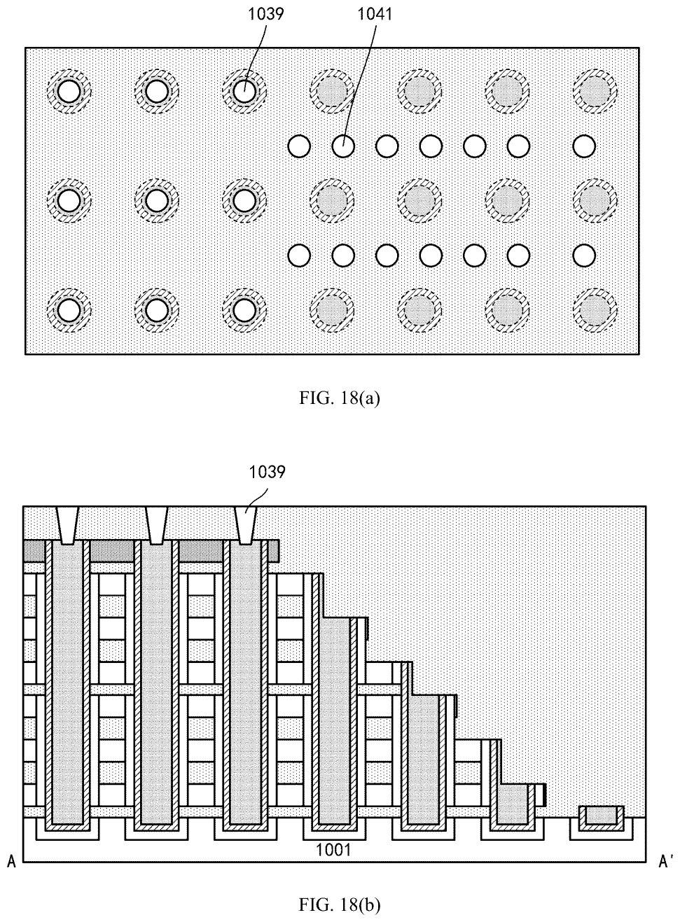

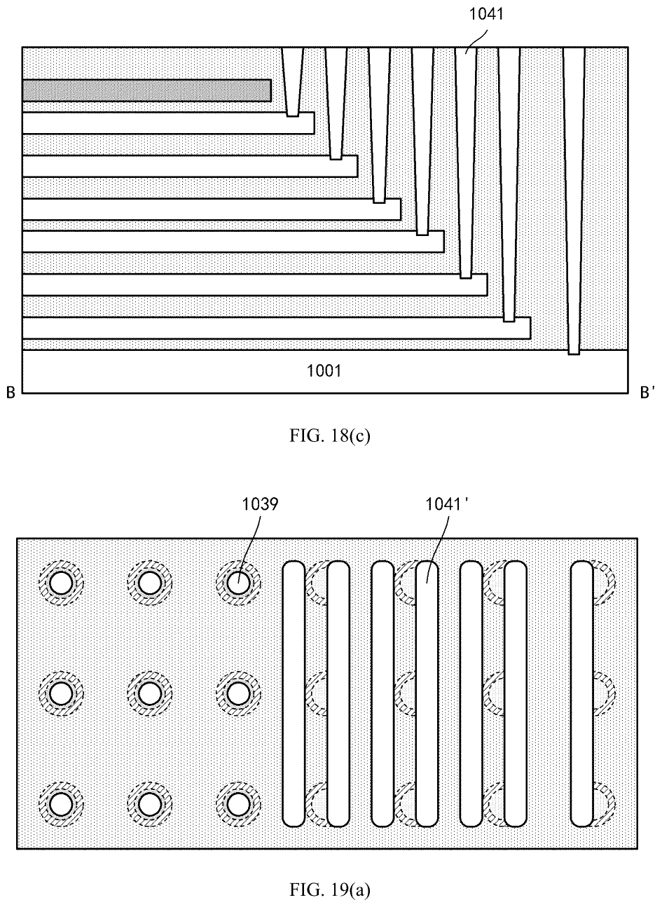

For example, as shown in FIGS. 17(a) and 17(b), an interlayer dielectric layer 1037 may be formed by depositing oxide and planarization such as CMP. Here, other oxide component such as the previously formed spacer 1035 is shown to be integral with the interlayer dielectric layer 1037 because both of them are made of oxides. Then, as shown in FIGS. 18(a), 18(b), and 18(c), contact portions 1039 and 1041 may be formed in the interlayer dielectric layer 1037. Specifically, the contact portion 1039 is formed in the device region and electrically connected to the gate conductor layer 1027 in the gate stack. The contact portion 1041 is formed in the contact region and electrically connected to each source/drain defining layer. The contact portion 1041 in the contact region may bypass the gate stack left in the contact region. Such contact portions may be formed by etching the interlayer dielectric layer 1037 to obtain holes and filling the holes with a conductive material such as a metal.

Here, the contact portion 1039 may be electrically connected to a word line. A gate control signal may be applied to the gate conductor layer 1027 through the word line via the contact portion 1039. For two memory cells stacked on each other in the same device layer, the source/drain defining layer located in the middle, i.e. the second source/drain defining layer 1009₁ or 1009₂, is shared by these two memory cells and may be electrically connected to the source line via the contact portion 1041; the source/drain defining layers located at upper and lower ends, i.e. the first source/drain defining layer 1005₁ or 1005₂ and the third source/drain defining layer 1013₁ or 1013₂, may be electrically connected to different bit lines via the contact portion 1041 respectively. In this way, a NOR-type configuration may be obtained.

Here, two memory cells are formed in one device layer, which may reduce the number of wirings. However, the present disclosure is not limited thereto. For example, only a single memory cell may be formed in one device layer. In this case, only the first source/drain defining layer, the first channel defining layer and the second source/drain defining layer may be provided in the device layer without the second channel defining layer and the third source/drain defining layer.

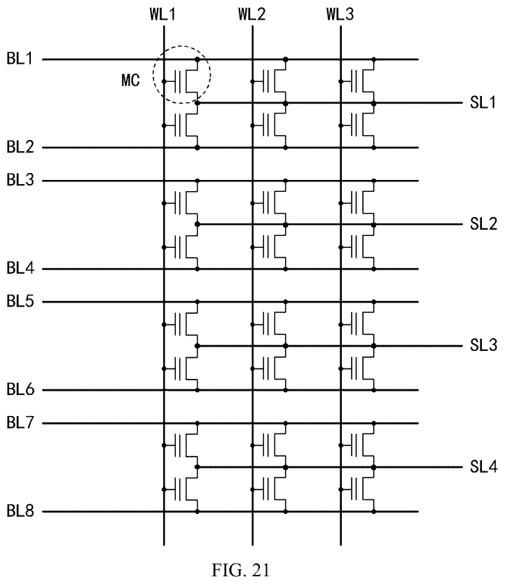

FIG. 21 schematically shows an equivalent circuit diagram of a NOR-type memory device according to an embodiment of the present disclosure.

In an example of FIG. 21, three word lines WL1, WL2, and WL3 and eight bit lines BL1, BL2, BL3, BL4, BL5, BL6, BL7, and BL8 are schematically shown. However, specific numbers of bit lines and word lines are not limited thereto. A memory cell MC is provided at an intersection of the bit line and the word line. FIG. 21 also shows four source lines SL1, SL2, SL3, and SL4. As described above, the adjacent memory cells of every two layers in the vertical direction may share the same source line connection. In addition, respective source lines may be connected to each other, so that respective memory cells MC may be connected to a common source line.

Here, a two-dimensional array of memory cells MC is shown for illustration convenience only. A plurality of such two-dimensional arrays may be arranged in a direction (for example, a direction perpendicular to the paper surface in FIG. 21) of intersection with this two-dimensional array, so as to obtain a three-dimensional array.

In FIG. 21, an extension direction of the word lines WL1 to WL3 may correspond to an extension direction of the gate stack, that is, the vertical direction with respect to the substrate in the above embodiment. In this direction, adjacent bit lines are isolated from each other. For this purpose, the isolation layer is arranged between adjacent device layers in the vertical direction in the above embodiment.

In the above embodiment, the contact portion 1041 in the contact region is desired to bypass the gate stack left in the contact region. According to another embodiment of the present disclosure, an isolation such as the dielectric material may be formed at a top end of the gate stack left in the contact region, so that it is not necessary to deliberately bypass the residual gate stack.

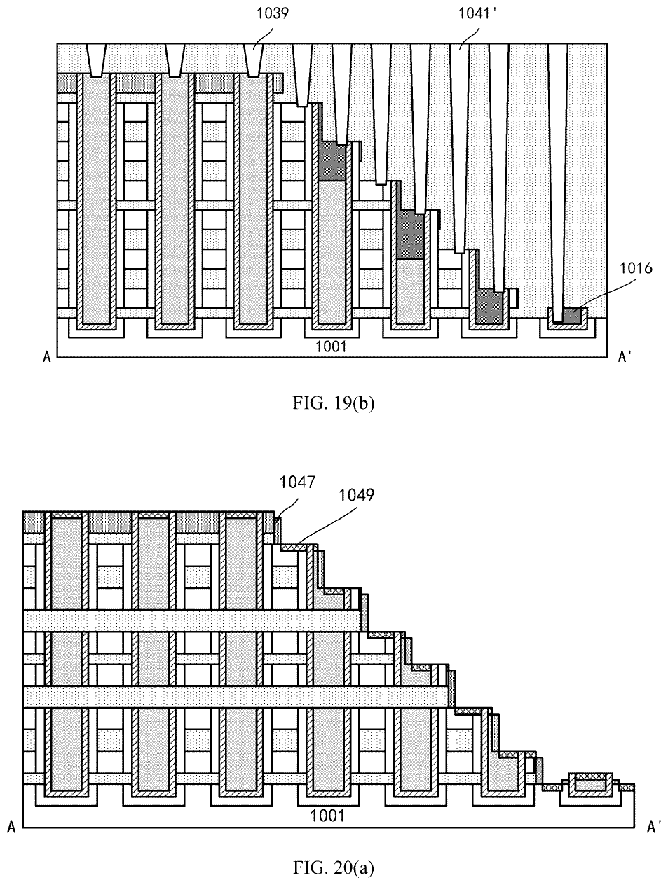

For example, as shown in FIGS. 19(a) and 19(b), after the step structure is formed in the contact region as described above in combination with FIGS. 14(a) to 16(b), the spacer 1035 may be removed by selective etching, such as RIE, so as to expose a top end of each gate stack (in the device region and the contact region). The gate stack in the device region may be shielded by a shielding layer, such as a photoresist, so as to expose the gate stack in the contact region. For the gate stack exposed in the contact region, the gate conductor layer may be recessed by a factor of, for example, about 50 nm to 150 nm, through selective etching such as RIE. After that, the shielding layer may be removed. A gap formed due to the recess of the gate conductor layer in the contact region may be filled with the dielectric material such as SiC by, for example, deposition and then etching back, so as to form an isolation plug 1016.

Next, the interlayer dielectric layer may be formed according to the above embodiment, and contact portions 1039 and 1041′ may be formed in the interlayer dielectric layer. In this example, the contact portion 1041′ in the contact region may extend into the isolation plug 1016. Therefore, the contact portion 1041′ may not be limited to be in form of plug described above, but may be formed as a strip, so as to reduce a contact resistance. The strip contact portion 1041′ may extend along a landing pad (i.e., the step in the step structure) of a corresponding layer.

In the above embodiment, the contact portion is in direct contact with the corresponding landing pad. According to another embodiment of the present disclosure, silicide may be formed at the landing pad, so as to reduce the contact resistance. More specifically, at each step of the contact region, a transverse surface of the step is used as a landing pad on which silicide may be formed. On the other hand, silicide may not be formed on a vertical surface of the step, so as to avoid a short circuit between landing pads of adjacent steps.

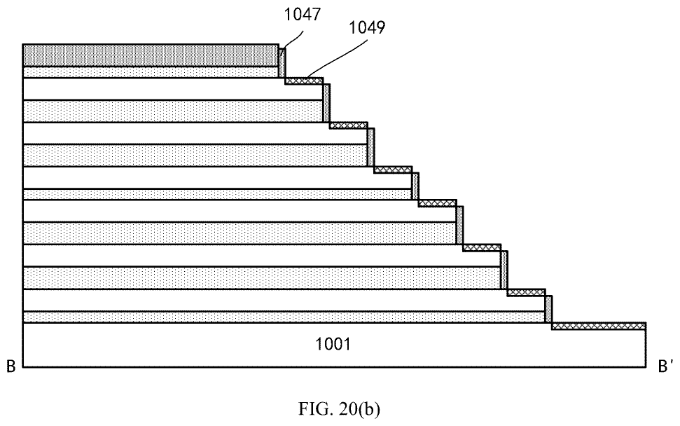

For example, as shown in FIGS. 20(a) and 20(b), after the step structure is formed in the contact region as described above in combination with FIGS. 14(a) to 16(b), the spacer 1035 may be removed by selective etching such as RIE, so as to expose a surface of each step in the contact region. A dielectric spacer 1047, such as nitride, may be formed on the vertical surface of each step by the spacer formation process, so as to shield the vertical surface of each step to avoid a subsequent silicification reaction. Then, an exposed transverse surface of each step may be silicified. For example, a metal such as NiPt may be deposited and annealed, so that silicification reaction is conducted between the deposited metal reacts and a semiconductor material (such as Si) at the transverse surface of each step, so as to generate a conductive metal silicide 1049 such as NiPtSi. An unreacted metal may then be removed.

In the example as shown, the gate conductor layer 1027 is polysilicon for example. Accordingly, a top end of the gate conductor layer 1027 may also undergo the silicification reaction and thus be covered by silicide. When the gate conductor layer 1027 is the metal gate, a protective layer (for example, nitride) may be formed on the device region to cover the gate stack and then be silicified. Accordingly, the gate conductor layer 1027 may be prevented from being damaged by etching when removing the metal in the silicification process.

Next, the interlayer dielectric layer may be formed as described above, and the contact portions 1039 and 1041 may be formed in the interlayer dielectric layer. When etching the hole used for the contact portion, the silicide 1049 may be used as an etching stop layer. Therefore, an etching depth of the hole may be better controlled.

The memory device according to the embodiments of the present disclosure may be applied to various electronic apparatuses. For example, the memory device may store various programs, applications and data required for an operation of the electronic apparatus. The electronic apparatus may further include a processor cooperated with the memory device. For example, the processor may operate the electronic apparatus by running a program stored in the memory device. Such electronic apparatus includes, for example, a smart phone, a personal computer (PC), a tablet, an artificial intelligence device, a wearable device, or a mobile power supply, etc.

In the above description, the technical details such as patterning and etching of each layer are not described in detail. However, those skilled in the art should understand that various technical means may be employed to form a layer, a region or the like having a desired shape. In addition, in order to form the same structure, those skilled in the art may also design a method that is not completely the same as the method described above. In addition, although the respective embodiments are described above separately, this does not mean that the measures in the respective embodiments cannot be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

1. A NOR-type memory device, comprising:
a gate stack extending vertically on a substrate, wherein the gate stack comprises a gate conductor layer and a memory functional layer; and
a first semiconductor layer and a second semiconductor layer that surround a periphery of the gate stack and extend along a sidewall of the gate stack, wherein the first semiconductor layer and the second semiconductor layer are respectively located at different heights with respect to the substrate,
wherein the memory functional layer is located between the first semiconductor layer and the gate conductor layer, and between the second semiconductor layer and the gate conductor layer,
wherein each of the first semiconductor layer and the second semiconductor layer comprises a first source/drain region, a channel region, and a second source/drain region that are disposed in sequence in a vertical direction, and
wherein a memory cell is defined at each of an intersection of the gate stack and the first semiconductor layer and an intersection of the gate stack and the second semiconductor layer.

2. The NOR-type memory device according to claim 1, wherein each of the first semiconductor layer and the second semiconductor layer further comprises a second channel region and a third source/drain region that are disposed in sequence in the vertical direction, so that the second channel region is located between the second source/drain region and the third source/drain region in the vertical direction, and two memory cells stacked on each other are defined at each of the intersection of the gate stack and the first semiconductor layer and the intersection of the gate stack and the second semiconductor layer.

3. The NOR-type memory device according to claim 1, wherein the memory functional layer comprises at least one of a charge trapping material or a ferroelectric material.

4. The NOR-type memory device according to claim 1, wherein the semiconductor layer comprises a single crystal semiconductor material.

5. The NOR-type memory device according to claim 1, wherein the memory functional layer is formed on a bottom surface of the gate conductor layer and a sidewall of the gate conductor layer.

6. The NOR-type memory device according to claim 1, wherein the first semiconductor layer is substantially coplanar to the second semiconductor layer in the vertical direction.

7. The NOR-type memory device according to claim 2, wherein an isolation layer is disposed between the first semiconductor layer and the second semiconductor layer.

8. The NOR-type memory device according to claim 7, wherein the source/drain region, which is adjacent to the isolation layer, of the semiconductor layer above the isolation layer among the first semiconductor layer and the second semiconductor layer, and the source/drain region, which is adjacent to the isolation layer, of the semiconductor layer below the isolation layer among the first semiconductor layer and the second semiconductor layer, are electrically connected to different bit lines respectively.

9. The NOR-type memory device according to claim 2, comprising a plurality of gate stacks arranged in an array, and first semiconductor layers and second semiconductor layers that surround the plurality of gate stacks respectively,
wherein the first semiconductor layers on peripheries of the plurality of gate stacks are substantially coplanar to each other in a transverse direction, and the second semiconductor layers on the peripheries of the plurality of gate stacks are substantially coplanar to each other in the transverse direction, and
wherein the first source/drain regions in the first semiconductor layers are substantially coplanar to each other in the transverse direction, the first channel regions in the first semiconductor layers are substantially coplanar to each other in the transverse direction, the second source/drain regions in the first semiconductor layers are substantially coplanar to each other in the transverse direction, the second channel regions in the first semiconductor layers are substantially coplanar to each other in the transverse direction, the third source/drain regions in the first semiconductor layers are substantially coplanar to each other in the transverse direction, the first source/drain regions in the second semiconductor layers are substantially coplanar to each other in the transverse direction, the first channel regions in the second semiconductor layers are substantially coplanar to each other in the transverse direction, the second source/drain regions in the second semiconductor layers are substantially coplanar to each other in the transverse direction, the second channel regions in the second semiconductor layers are substantially coplanar to each other in the transverse direction, and the third source/drain regions in the second semiconductor layers are substantially coplanar to each other in the transverse direction.

10. The NOR-type memory device according to claim 9, wherein the substrate comprises a device region and a contact region adjacent to the device region, the memory cell is formed on the device region, and the NOR-type memory device further comprises:
a first bit line and a second bit line that is different from the first bit line;
a source line;
a first interconnection layer extending transversely, wherein the first interconnection layer surrounds the first source/drain region in each first semiconductor layer on the periphery of each gate stack and extends to the contact region;
a second interconnection layer extending transversely, wherein the second interconnection layer surrounds the second source/drain region in each first semiconductor layer on the periphery of each gate stack and extends to the contact region; and
a third interconnection layer extending transversely, wherein the third interconnection layer surrounds the third source/drain region in each first semiconductor layer on the periphery of each gate stack and extends to the contact region;
wherein the first interconnection layer and the third interconnection layer are electrically connected to the first bit line and the second bit line respectively, and the second interconnection layer is electrically connected to the source line.

11. The NOR-type memory device according to claim 10, wherein the first interconnection layer, the second interconnection layer, and the third interconnection layer comprise a doped single crystal semiconductor material.

12. The NOR-type memory device according to claim 10, wherein:
the first interconnection layer is substantially coplanar to the first source/drain region in each first semiconductor layer in the transverse direction,
the second interconnection layer is substantially coplanar to the second source/drain region in each first semiconductor layer in the transverse direction, and
the third interconnection layer is substantially coplanar to the third source/drain region in each first semiconductor layer in the transverse direction.

13. The NOR-type memory device according to claim 10, wherein a dielectric material is disposed between the first interconnection layer and the second interconnection layer, and between the second interconnection layer and the third interconnection layer.

14. The NOR-type memory device according to claim 10, further comprising:
a first contact portion to the first interconnection layer in the contact region;
a second contact portion to the second interconnection layer in the contact region; and
a third contact portion to the third interconnection layer in the contact region,
wherein the first interconnection layer is electrically connected to the first bit line via the first contact portion, the third interconnection layer is electrically connected to the second bit line via the third contact portion, and the second interconnection layer is electrically connected to the source line via the second contact portion.

15. The NOR-type memory device according to claim 14, wherein the first contact portion, the second contact portion, and the third contact portion are formed as strips extending substantially parallel to each other.

16. The NOR-type memory device according to claim 10, wherein the first interconnection layer, the second interconnection layer, and the third interconnection layer form a step structure in the contact region.

17. The NOR-type memory device according to claim 16, wherein the step structure comprises a step with a transverse surface and a vertical surface, and the NOR-type memory device further comprises:
a silicide on the transverse surface of the step; and
a dielectric spacer on the vertical surface of the step.

18. The NOR-type memory device according to claim 1, further comprising:
a word line; and
a fourth contact portion to the gate conductor layer, wherein the fourth contact portion is electrically connected to the word line.

19. The NOR-type memory device according to claim 1, wherein each of the first semiconductor layer and the second semiconductor layer is a nanosheet extending vertically and having annular cross-section.

20. A method of manufacturing a NOR-type memory device, comprising:
disposing a plurality of device layers on a substrate, wherein each of the plurality of device layers comprises a stack of a first source/drain defining layer, a first channel defining layer, and a second source/drain defining layer;
forming a processing channel that extends vertically with respect to the substrate to pass through the stack in each device layer;
epitaxially growing a semiconductor layer on a sidewall of each device layer exposed in the processing channel through the processing channel; and
forming a gate stack in the processing channel, wherein the gate stack comprises a gate conductor layer and a memory functional layer disposed between the gate conductor layer and the semiconductor layer, and a memory cell is defined at an intersection of the gate stack and the semiconductor layer.

21. The method according to claim 20, wherein the stack of at least one of the plurality of device layers further comprises a second channel defining layer and a third source/drain defining layer.

22. The method according to claim 20, wherein the stack is formed by epitaxial growth.

23. The method according to claim 22, wherein at least each source/drain defining layer in the stack is doped in situ during epitaxial growth.

24. The method according to claim 23, further comprising:
performing an annealing treatment, so that a dopant in the stack diffuses transversely into the semiconductor layer.

25. The method according to claim 20, further comprising:
recessing the sidewall of the device layer exposed in the processing channel to a certain depth in a transverse direction by etching via the processing channel.

26. The method according to claim 25, wherein respective sidewalls of the plurality of device layers are substantially coplanar to each other in the vertical direction after being recessed.

27. The method according to claim 20, further comprising:
forming a sacrificial layer between at least one pair of adjacent device layers,
wherein after disposing the plurality of device layers, the method further comprises replacing the sacrificial layer by an isolation layer.

28. The method according to claim 27, wherein replacing the sacrificial layer by the isolation layer comprises:
forming a support layer in one or more of processing channels, so that the sacrificial layer is exposed in the rest of the processing channels;
replacing the sacrificial layer by the isolation layer via the rest of the processing channels; and
removing the support layer.

29. The method according to claim 28, wherein replacing the sacrificial layer by the isolation layer comprises:
recessing the channel defining layer and the sacrificial layer to a first depth in a transverse direction by selective etching via the rest of the processing channels;
forming a position holding plug in a first gap formed by the recessing of the sacrificial layer, wherein a thickness of the sacrificial layer is less than a thickness of the channel defining layer, so that the position holding plug is not formed in a second gap formed by the recessing of the channel defining layer;
forming a protective plug in the second gap; and
removing the position holding plug by selective etching, so as to expose the sacrificial layer.

30. The method according to claim 29, wherein epitaxially growing the semiconductor layer comprises:
recessing the source/drain defining layer to a second depth in the transverse direction by selective etching via the rest of the processing channels, wherein the second depth is substantially equal to the first depth;
removing the protective plug and the support layer by selective etching;
shielding the rest of the processing channels by using a shielding layer, so that the one or more of the processing channels is exposed;
recessing a sidewall of the device layer exposed in the one or more of the processing channels to a third depth in the transverse direction by selective etching via the one or more of the processing channels, wherein the third depth is substantially equal to the first depth;
removing the shielding layer; and
epitaxially growing the semiconductor layer on the sidewall of the device layer exposed in each processing channel.

31. The method according to claim 20, wherein forming the gate stack comprises:
forming the memory functional layer on a bottom surface of the processing channel and a sidewall of the processing channel in a substantially conformal manner; and
filling the processing channel, on which the memory functional layer is formed, with the gate conductor layer.

32. The method according to claim 20, wherein a plurality of processing channels arranged in an array are formed.

33. The method according to claim 20, further comprising:
removing each channel defining layer in the device layer by selective etching; and
filling a gap obtained by the removing of the channel defining layer with a dielectric.

34. The method according to claim 21, wherein the substrate comprises a device region and a contact region adjacent to the device region, the memory cell is formed on the device region, and the method further comprises:
forming, on the contact region, a first contact portion to the first source/drain defining layer, a second contact portion to the second source/drain defining layer, and a third contact portion to the third source/drain defining layer.

35. The method according to claim 30, wherein the first contact portion, the second contact portion, and the third contact portion are formed as strips extending substantially parallel to each other.

36. The method according to claim 34, further comprising:
patterning the first source/drain defining layer, the second source/drain defining layer, and the third source/drain defining layer in each device layer into a step structure in the contact region.

37. The method according to claim 36, wherein the step structure comprises a step with a transverse surface and a vertical surface, and the method further comprises:
forming a dielectric spacer on the vertical surface of the step; and
siliconizing the transverse surface of the step.

38. An electronic apparatus comprising the NOR-type memory device according to claim.

39. The electronic apparatus according to claim 38, wherein the electronic apparatus comprises a smart phone, a computer, a tablet, an artificial intelligence device, a wearable device, or a mobile power supply.
